(19) United States
(12) Patent Application Publication
(10) Pub. No.: US 2025/0038478 A1
(43) Pub. Date: Jan. 30, 2025

(54) SURFACE-EMITTING PHOTONIC CRYSTAL LASER, OPTOELECTRONIC SYSTEM, AND METHOD FOR PRODUCING A SURFACE-EMITTING PHOTONIC CRYSTAL LASER

(71) Applicant: ams-OSRAM International GmbH, Regensburg (DE)

(72) Inventor: Martin BEHRINGER, Regensburg (DE)

(73) Assignee: ams-OSRAM International GmbH, Regensburg (DE)

(21) Appl. No.: 18/719,003

(22) PCT Filed: Oct. 24, 2022
(86) PCT No.: PCT/EP2022/079570

§ 371 Date: Jun. 12, 2024

(30) Foreign Application Priority Data
Dec. 14, 2021 (DE) 10 2021 214 311.3

(51) Int. Cl. H01S 5/10; H01S 5/11

(52) U.S. Cl. CPC H01S 5/1017; H01S 5/11

(57) ABSTRACT

The invention relates to a surface-emitting photonic crystal laser (1). The laser has an active layer for generating electromagnetic radiation by combining charge carriers, wherein the active layer has a first main surface and a second main surface lying opposite the first main surface. The first main surface is equipped with a first waveguide layer, and the second main surface is equipped with a second waveguide layer, said waveguide layers having regions which are arranged periodically relative to one another and additional regions which have different refractive indices and which form a photonic crystal. The first waveguide layer is equipped with a first casing layer which has at least one p-connection region for injecting electrically positive charge carriers into the active layer and at least one n-connection region for injecting electrically negative charge carriers into the active layer. The invention additionally relates to a method for producing a surface-emitting photonic crystal laser and to an optoelectronic system.

### CROSS-REFERENCE TO RELATED APPLICATIONS

The present application is a national stage entry from International Application No. PCT/EP2022/079570, filed on Oct. 24, 2022, published as International Publication No. WO 2023/110203 A1 on Jun. 22, 2023, and claims priority to German Patent Application No. 10 2021 214 311.3, filed Dec. 14, 2021, the disclosures of all of which are hereby incorporated by reference in their entireties.

### BACKGROUND

Structures that are formed by periodic modulation of the refractive index of the medium used are referred to as photonic crystals. A photonic-crystal surface-emitting laser (PCSEL), herein sometimes referred to as a laser or PCSEL for short, comprises an active layer that emits electromagnetic radiation when a driving current is applied. Doped layers, in particular waveguide layers and cladding layers, may be arranged on both sides of the active layer. Furthermore, electrical contacts may be located on both sides of the active layer, wherein at least one electrical contact is patterned in order to outcouple electromagnetic radiation via the correspondingly patterned surface. This structure may lead to inhomogeneous current impression and/or shadowing. Alternatively, in order to contact the active layer from only one side, vias may be provided through the waveguide layer. This may result in the beam quality of the laser degrading due to absorption caused by dopants, light scattering at vias and filamentation of the wave in the waveguide.

It is at least one object of certain embodiments to provide a surface-emitting photonic-crystal laser of high beam quality. It is another object of certain embodiments to provide an optoelectronic system comprising such a PCSEL. Furthermore, it is an object of certain embodiments to disclose a method for manufacturing such a PCSEL.

These objects are achieved by the subject matter according to the independent claims. Advantageous embodiments and further embodiments of the subject matter are characterized in the dependent claims and are further apparent from the following description and the drawings.

### SUMMARY

According to at least one embodiment, a surface-emitting photonic-crystal laser, PCSEL, comprises an active layer for generating electromagnetic radiation by charge carrier recombination. Electromagnetic radiation may herein be referred to as “radiation” or “light”. Radiation or light may, in particular, denote electromagnetic radiation of one or more wavelengths or wavelength ranges. The active layer comprises a first main surface and a second main surface opposite the first main surface. The active layer has a main extension plane that extends in lateral directions. The first and second main surfaces run parallel to the lateral directions. The active layer has a thickness in a transversal direction perpendicular to the lateral directions.

According to at least one embodiment, the laser further comprises a first waveguide layer arranged on the first main surface of the active layer and a second waveguide layer arranged on the second main surface of the active layer. In other words, the active layer is arranged between the first and second waveguide layers. The electromagnetic radiation generated by the active layer is guided in the first and second waveguide layers. The first and second waveguide layers form a waveguide into which the active layer is embedded. An optical wave is guided in the waveguide in a lateral direction.

According to at least one embodiment, the second waveguide layer comprises regions and further regions arranged periodically with respect to one another. A refractive index of the regions differs from a refractive index of the further regions. The regions and the further regions thus form a photonic crystal. In particular, the regions and the further regions form a 2-dimensional (2D) photonic crystal. The photonic crystal is configured to influence the electromagnetic radiation generated by the active layer. In particular, the photonic crystal scatters the radiation in the transversal direction. For example, a material of the second waveguide layer, in particular a semiconductor material, forms the regions of the second waveguide layer. The further regions may be defined by a further material of the second waveguide layer. For example, the further material comprises an oxide, air or a gas. In particular, the further regions have a significantly lower refractive index than the corresponding semiconductor material used in the second waveguide layer. The regions and the further regions are arranged regularly with respect to one other. This may mean that the further regions are arranged in a matrix or are located on intersections of a lattice when viewed from a top view. This may be an oblique-angled, rectangular, centered-rectangular, hexagonal or square lattice. The lattice may consist of a base made up of several elements. A lattice period may be selected to substantially coincide with a wavelength of the radiation generated by the active layer, or to substantially coincide with a multiple of that wavelength. In this way, the Bragg condition is satisfied in order to achieve 2D feedback in the plane of the photonic crystal and light emission perpendicular to it. Here, the lattice period is defined by the periodically arranged regions or further regions. In the second waveguide layer, the wavelength of the electromagnetic radiation depends on an effective refractive index, wherein

$${λ}_{o} = {λ}_{G} \cdot {n}_{eff}$$

applies, with λₒ being the vacuum wavelength, λ_{G} being the wavelength in the second waveguide layer and n_{eff} being the effective refractive index. The effective refractive index of the second waveguide layer is based on the refractive indices of the regions and further regions, and on their proportions in the second waveguide layer. This means that the choice of a diameter of the further regions influences the wavelength in the second waveguide layer. The ratio between the diameter of the further regions and the lattice period may be chosen to be as small as possible in order to improve a quality factor (Q factor) of the emission. A high Q factor reduces the lasing threshold of the laser and leads to wavelength-mode resonance with low attenuation. On the other hand, a larger diameter of the further regions improves the refractive index contrast of the photonic crystal.

Electromagnetic radiation traveling through the photonic crystal is scattered at the interfaces between the regions and the further regions, i.e. generally at non-uniformities. Scattered waves of electromagnetic radiation may interfere with each other and with the original wave in a constructive manner or a destructive manner. Since these non-uniformities, i.e. in this case the regions and the further regions, are periodically distributed, it may be possible to achieve complete destructive interference or the formation of coherent radiation. Depending on its frequency and the lattice periodicity of the photonic crystal, electromagnetic radiation may only propagate in certain directions of the lattice and is reflected if it is directed in so-called forbidden directions. This may lead to formation of a standing wave, with the radiation being repeatedly scattered by various non-uniformities and constructively interferes within itself. The standing wave is formed by several Bragg diffractions.

Photonic crystals, in particular 2D photonic crystals, may be used advantageously in laser arrangements, thereby forming a so-called photonic-crystal surface-emitting laser, PCSEL. The stimulated light emission is achieved by coupling the modes of the photonic crystal with the active layer of the laser. This results in the feedback effect described above within the crystal plane. Coherent radiation is also emitted perpendicular to the crystal surface by first-order Bragg diffraction. It is also possible for coherent radiation to be emitted at an angle other than 90° to the crystal surface. The emitted radiation may be characterized above all by its monomodicity, its narrow radiation profile and its high output power over a large radiation area.

According to at least one embodiment, the laser further comprises a first cladding layer arranged on the first waveguide layer. In other words, the first waveguide layer is arranged between the active layer and the first cladding layer. The first cladding layer may be configured to keep the optical wave guided in the lateral direction in the waveguide. For this purpose, the first cladding layer may have a lower refractive index than the first waveguide layer, such that the lateral optical wave is reflected, in particular totally reflected, at the interface between the first waveguide layer and the first cladding layer. Optionally, the laser further comprises a second cladding layer having corresponding properties (in particular a lower refractive index than the second waveguide layer), which is arranged on the second waveguide layer. In other words, the second waveguide layer is arranged between the active layer and the optional second cladding layer. Alternatively, the laser does not comprise a second cladding layer. In this case, the optical wave is reflected at the interface between the second waveguide layer and the environment, e.g. air. Air generally has a very low refractive index (n≈1) and therefore enables total internal reflection. Without a second cladding layer, the manufacturing costs of the laser may therefore be reduced.

According to at least one embodiment, the first cladding layer comprises at least one p-connection region for injecting electrically positive charge carriers into the active layer. The first cladding layer also comprises at least one n-connection region for injecting electrically negative charge carriers into the active layer. Electrically positive charge carriers may also be referred to as holes. Electrically negative charge carriers may also be referred to as electrons. Electrons and holes recombine in the active layer, thereby emitting electromagnetic radiation. The first cladding layer may comprise one or more than one p-connection region. The first cladding layer may comprise one or more than one n-connection region. All information given here and in the following regarding a p-connection region or an n-connection region may apply accordingly to all other p- or n-connection regions. The connection regions (n- and/or p-) may be separate and spaced-apart regions of the first cladding layer. Alternatively, the connection regions may also be non-overlapping regions of the first cladding layer. The connection regions (n- and/or p-) may, for example, be produced by implantation or diffusion of dopant atoms of the n-type or p-type. It is also possible for corresponding dopant atoms to be introduced into the first cladding layer by adding certain process gases even while growing first cladding layer. For example, the first cladding layer is an n-doped, undoped or intrinsically doped layer, with the p-connection regions being formed by p-implantation (or counter-implantation). In this example, the remaining regions of the first cladding layer may form the n-connection regions. Alternatively, the first cladding layer is a p-doped, undoped or intrinsically doped layer, with the n-terminal regions being formed by n-implantation, i.e. implantation of a dopant of the n-type (or counter-implantation), and the remaining regions of the first cladding layer forming the p-connection regions. The charge carrier transport to the active layer via the n-connection regions and/or p-connection regions takes place in particular due to diffusion. This may mean that charge carriers diffuse through the first waveguide layer. The positive charge carriers and the negative charge carriers are injected into the active layer from the same side with regard to the direction of growth.

The active layer, the first and second waveguide layers and/or the first and second (if present) cladding layers may preferably comprise a semiconductor material. The semiconductor material is, for example, a III-V compound semiconductor material. The semiconductor material is, for example, a nitride compound semiconductor material, such as AlₙIn₁₋ₙ₋ₘGaₘN, or a phosphide compound semiconductor material, such as AlₙIn₁₋ₙ₋ₘGaₘP, or an arsenide compound semiconductor material, such as AlₙIn₁₋ₙ₋ₘGaₘAs or AlₙIn₁₋ₙ₋ₘGaₘAsP, or an antimonide compound semiconductor material, such as AlₙIn₁₋ₙ₋ₘGaₘSb, or AlInGaAsN or a mixture of the above compound semiconductor materials, where 0≤n≤1, 0≤m≤1 and m+n≤1 in each case. A semiconducting layer may contain dopants and additional components. For the sake of simplicity, however, only the essential components of the crystal lattice of the semiconducting layer, i.e. Al, As, Ga, In, N, P or Sb, are specified, even if these may be partially replaced and/or supplemented by small amounts of other substances. The active layer, the first and second waveguide layers and/or the first and second (if present) cladding layers may be grown epitaxially. In particular, the active layer, the first and second waveguide layers, and the first and second cladding layers may be grown in a continuous epitaxial process. The uninterrupted epitaxy process may increase the material quality, as the possibility of contamination by foreign atoms and crystal defects is reduced. However, it is also possible to not apply the first and/or second cladding layer epitaxially. It is also possible to not apply the second waveguide layer epitaxially. This is possible because the material requirements for the second waveguide layer and/or the second cladding layer are lower in terms of electrical properties (according to the invention, no current is conducted via these layers).

The PCSEL is characterized in particular by the fact that charge carriers are injected into the active layer from one side only, namely via the first cladding layer and the first waveguide layer. This avoids shadowing due to top-side contact on the radiation outcoupling side, which may be particularly serious with large laser diameters and high drive currents. The PCSEL may therefore be scaled to any size. This also allows for any small divergence angle of the outcoupled radiation to be achieved. The connection regions and possible electrical contacts via which the charge carriers are injected into the active layer may be distributed over the first cladding surface as required in order to improve current distribution and achieve higher laser power. No charge carriers are injected into the active layer via the second waveguide layer. This means that the side of the structure facing away from the connection regions, in particular the second waveguide layer, does not necessarily have to be doped. The efficiency of the laser may thus be increased, as absorption of the optical wave by dopants is avoided.

According to at least one embodiment, a surface-emitting photonic-crystal laser comprises an active layer for generating electromagnetic radiation by charge carrier recombination, wherein the active layer comprises a first main surface and a second main surface opposite the first main surface. The laser also comprises a first waveguide layer arranged on the first main surface. The laser further comprises a second waveguide layer arranged on the second main surface, the second waveguide layer comprising regions and further regions arranged periodically with respect to one another, wherein a refractive index of the regions differs from a refractive index of the further regions, and wherein the regions and the further regions form a photonic crystal. The laser also comprises a first cladding layer arranged on the first waveguide layer, the first cladding layer comprising at least one p-connection region for injecting electrically positive charge carriers into the active layer and at least one n-connection region for injecting electrically negative charge carriers into the active layer. According to at least one embodiment, the second waveguide layer comprises a material defining the regions of the second waveguide layer. According to at least one embodiment, as specified above, the second waveguide layer comprises a semiconductor material, in particular a III-V compound semiconductor material. However, it is also possible for the second waveguide layer to comprise a different material or material system. In particular, the material or material system of the second waveguide layer may differ from the material or material system of the other layers (active layer, first waveguide layer, first cladding layer). In laser structures, the same material system may be used for the layers contained therein in order to reduce crystal defects and thus improve the electrical properties, such as electrical conductivity. Since the present example embodiments are based on a driving current being injected via the first waveguide layer into the active layer only, the material requirements for the second waveguide layer in terms of electrical properties are lower. Instead, a material may be selected with regard to optical properties, such as refractive index and/or absorption. The second waveguide layer may therefore comprise other materials, such as silicon, magnesium and/or fluoride compounds.

According to at least one embodiment, the further regions of the second waveguide layer are defined by recesses of the second waveguide layer. This may mean that the second waveguide layer is patterned, wherein areas in which the above-mentioned material of the second waveguide layer has been removed form the further regions of the second waveguide layer. The further regions may comprise air or a gas. Alternatively, the recesses are filled with a further material, e.g. an oxide. The further regions may therefore have a lower refractive index than the regions of the second waveguide layer. The regions of the second waveguide layer may also be referred to as high refractive index zones. The further regions of the second waveguide layer may also be referred to as low refractive index zones.

According to at least one embodiment, the recesses of the second waveguide layer are formed by trenches or holes in the second waveguide layer. The trenches extend from a surface of the second waveguide layer facing away from the active layer into the second waveguide layer. The trenches are introduced in dedicated areas of the second waveguide layer. According to one embodiment, a diameter of the trenches is in the nanometer range. For example, the trenches have a diameter of at least 5 nm and at most 1000 nm. Preferably, the trenches have a diameter of at least 10 nm and at most 50 nm. The trenches may also be referred to as holes or nano-holes, and vice versa. The shape of the trenches may be cylindrical, i.e. when viewed from a top view, the trenches may have a circular or elliptical profile. However, it is also possible for the trenches to have a different profile, e.g. polygonal, in particular triangular or quadrangular. Furthermore, it is also possible that at least two trenches have different profiles. The profile of the trenches affects a mode profile of the photonic crystal. For example, certain symmetries may lead to so-called “leaky modes” or “non-leaky modes” and may thus influence the radiation efficiency of the laser array. In the transversal direction, the trenches terminate in the second waveguide layer. This means that a trench foot is located in the second waveguide layer. The trench foot of a respective trench is spaced apart from the active layer. In the transversal direction (i.e. the growth direction), a depth of the trenches may correspond to 10-80%, 50-80% or 70-80% of the thickness of the second waveguide layer. In other words, the trenches may penetrate the second waveguide layer by up to 80%. In particular, this may mean that an overlap of the optical wave with the trenches may be large. The trenches are arranged regularly with respect to one other. This may mean that the trenches are arranged in a matrix or are located on intersections of a lattice when viewed from a top view, wherein a lattice period may be chosen such that it coincides with a wavelength of the radiation generated by the active layer, with an integer multiple of the wavelength, or with a non-integer multiple of the wavelength, as described above. A photonic crystal may be efficiently formed by the trenches. In particular, no regrowth is required as the trenches may be introduced into the (undoped) second waveguide layer at the end of a fabrication process. Time-consuming and expensive process steps may therefore be avoided, making mass production much easier. Since the layers used may be produced using an uninterrupted epitaxy process, the material quality may also be increased as the possibility of contamination with foreign atoms and crystal defects is reduced.

According to at least one alternative embodiment, the further regions are embedded into the second waveguide layer. In particular, this may mean that the further regions do not extend up to the surface of the second waveguide layer 15. Such an arrangement may be produced using a regrowth process, for example.

According to at least one embodiment, the first waveguide layer is undoped or intrinsically doped. Herein undoped or intrinsically doped means, for example, a doping concentration of at most 1·10¹⁶ cm⁻³ or at most 1·10¹⁵ cm⁻³. The first waveguide layer may be formed to be thin, so that charge carriers may diffuse through the first waveguide layer despite its low doping concentration in order to recombine in the active layer. Absorption of the optical waves by dopants may thus be avoided or reduced.

Alternatively, at least regions of the first waveguide layer comprise a p-doping and/or an n-doping. In this case, the doping concentration there is preferably at most 1·10¹⁹ cm⁻³ or at most 1·10¹⁸ cm⁻³ or at most 1·10¹⁷ cm⁻³. Along the lateral direction, regions in the first waveguide layer having a p-doping may alternate with undoped regions or regions having an n-doping. The respective regions may correspond to the p-connection regions or n-connection regions of the first cladding layer, i.e. be aligned with them. The doping may facilitate diffusion in the direction of the active layer.

According to at least one embodiment, the second waveguide layer is undoped or intrinsically doped. As specified above, undoped or intrinsically doped herein may mean a doping concentration of at most 1·10¹⁶ cm⁻³ or at most 1·10¹⁵ cm⁻³, for example. The second waveguide layer does not carry any drive current. Absorption of the optical waves by dopants and non-radiative recombination of charge carriers in this layer may therefore be avoided or reduced. This means that the beam quality and the light image of the laterally traveling optical wave are improved. Interference due to charge carrier densities is reduced and filaments of high light intensity are avoided. In other words, the so-called α-factor (also known as the “linewidth enhancement factor”) is reduced. Increased spectral widths may result from a coupling between intensity and phase noise, which is caused by the dependence of the refractive index on the charge carrier density in the semiconductor.

According to at least one embodiment, a thickness of the first waveguide layer is less than a thickness of the second waveguide layer. Herein thickness refers to the expansion of the respective layer in the transversal direction (growth direction). Alternatively, the thickness of the first waveguide layer is equal to the thickness of the second waveguide layer within the manufacturing tolerances. It is also possible for the thickness of the first waveguide layer to be greater than the thickness of the second waveguide layer. The first waveguide layer and the second waveguide layer together form a waveguide into which the active layer is embedded. The waveguide may have a total thickness of a minimum of 0.1 μm and a maximum of 10 μm. Alternatively, the total thickness is between 0.5 μm and 2 μm. If the thickness of the first waveguide layer is identical to the thickness of the second waveguide layer, the position of the active layer in the waveguide is centered, so that a symmetrical waveguide design is realized. Otherwise, an asymmetrical waveguide design is realized, in which the position of the active layer in the waveguide may be at 10-90% in terms of the total thickness of the waveguide. Preferably, the thickness of the first waveguide layer is less than the thickness of the second waveguide layer. For example, the second waveguide layer is 2 to 5 times thicker than the first waveguide layer. In this case, a distance between the active layer and a surface of the first waveguide layer facing away from the active layer (on which the first cladding layer is located) is smaller than a distance between the active layer and a surface of the second waveguide layer facing away from the active layer (on which the second cladding layer may be located). In this manner, the charge carrier injection may be increased, since a diffusion path is reduced. Furthermore, in this manner, large parts of the optical wave guided in the waveguide are located in the second waveguide layer in which the photonic crystal is arranged. In particular, a maximum of the intensity distribution of the wave is located in the second waveguide layer. This means that the optical crystal may have a strong influence on the wave.

According to at least one embodiment, the laser further comprises a second cladding layer arranged on the second waveguide layer. In other words, the second waveguide layer is arranged between the active layer and the second cladding layer. The second cladding layer may be configured to keep the optical wave guided in the lateral direction within the waveguide. For this purpose, the second cladding layer may have a lower refractive index than the second waveguide layer, so that the laterally traveling optical wave is reflected, in particular totally reflected, at the interface between the second waveguide layer and the second cladding layer.

According to at least one embodiment, the second cladding layer is undoped or intrinsically doped. The second cladding layer may be undoped or intrinsically doped, as no charge carriers are transported via the second cladding layer. Therefore, a material having a high band gap—which corresponds to a low refractive index—may be chosen for the second cladding layer regardless of dopability. This may mean that a material or material system of the second cladding layer differs from a material or material system of the first cladding layer.

According to at least one embodiment, the recesses of the second waveguide layer are formed by trenches in the second waveguide layer, which extend from a surface of the second cladding layer facing away from the second waveguide layer into the second waveguide layer. This may mean that the second cladding layer becomes patterned also when the trenches are introduced, as discussed above. Due to the flexible choice of material, the second cladding layer may be thin, in particular thinner than the first cladding layer. This facilitates the patterning of the second cladding layer and the second waveguide layer underneath, which means in particular that the profile of the trenches introduced may be formed true to the pattern.

According to at least one embodiment, the active layer forms at least one quantum well which is intended and configured to imitate electromagnetic radiation of a predetermined wavelength when a driving current is applied. For this purpose, the active layer preferably comprises at least one quantum well in the form of a 2D quantum well or a 1D quantum well (quantum wire) or a 0D quantum well (quantum dot). For example, the recombination layer comprises a plurality of 2D quantum wells arranged one above the other in the transversal direction, each separated by a barrier layer. This may mean that the active layer may comprise a plurality of semiconductor layers forming at least one quantum well. A 2D quantum well may be formed by a thin intermediate layer of a first material, e.g. about 4-5 nm thick, surrounded by barrier layers of a second material, e.g. about 3-10 nm thick. The barrier layers have a larger band gap than the intermediate layer. This creates a potential gradient in the conduction and valence band between the two groups of materials, thereby forming a potential minimum in the intermediate layer. Due to the quantization of the system, charge carriers in the interlayer may assume discrete energy values only. In one embodiment, the active layer forms at least one quantum well and at most one hundred quantum wells. Preferably, the active layer forms between two and ten quantum wells inclusive. The active layer may also be referred to as a “multiple quantum well”, MQW. A first and a final layer, as viewed in the growth direction (transversal direction) of the layer stack formed by the active layer, may be provided and configured to confine charge carriers in the active layer, i.e. to prevent them from leaving the active layer (“confinement”). This means that the first and the final layers may be embodied as so-called “confinement layers” with a larger band gap. Alternatively, the active layer may comprise a plurality of quantum dots. The quantum dots may be arranged next to each other in a plane parallel to the main extension plane of the active layer. The active layer may also comprise a plurality of stacked planes parallel to the main extension plane of the active layer, each with a plurality of quantum dots within these planes. The different levels of quantum dots are then preferably separated from each other by barrier layers. Quantum wells enable laser emission at dedicated wavelengths from a broad spectral range while simultaneously providing high power and low threshold current.

According to at least one embodiment, a radiation direction of the laser is perpendicular to a main extension plane of the second waveguide layer. Electromagnetic radiation is outcoupled via a surface of the second waveguide layer facing away from the active layer. The radiation generated by the active layer is influenced by the photonic crystal in such a manner that electromagnetic fields interfere constructively or destructively with each other in the crystal due to diffraction effects. This may lead to the formation of a standing wave within the waveguide. First-order Bragg diffraction also causes coherent light to be emitted perpendicular to the photonic crystal, i.e. perpendicular to the main extension plane of the waveguide. The emitted light may be outcoupled via the surface of the second waveguide layer opposite the active layer or via the surface of the second cladding layer. It is also possible for the light to be outcoupled at an angle other than 90°, i.e. not necessarily perpendicular to the main extension plane of the waveguide.

According to at least one embodiment, the laser further comprises a reflective layer arranged on or above the first cladding layer. The reflective layer may be a dedicated layer on or above the first cladding layer. According to one embodiment, the reflective layer is formed by electrical contact elements by means of which the connection elements of the first cladding layer are connected. For example, the reflective layer comprises a metal, such as gold (Ag), titanium (Ti), silver (Ag), platinum (Pt) and/or palladium (Pd). The reflective layer causes the electromagnetic radiation scattered perpendicular in the direction of the first cladding layer by the photonic crystal to be reflected back so that the electromagnetic radiation is preferably outcoupled via the second cladding surface opposite the first cladding surface.

According to at least one embodiment, the first cladding layer comprises a plurality of individual and independently controllable p-connection regions and/or a plurality of individual and independently controllable n-connection regions. The first and second connection elements may be electrically contacted or energized individually and independently of one another. This means that the first and second connection elements are not directly electrically connected to each other. Due to the individual and independently controllable connection regions (p- and/or n-), an inhomogeneous current impression may be achieved, i.e. individual connection regions may be operated with different currents. This means that a current density may be varied in lateral directions. The current density may be adjusted to excite certain optical modes.

According to at least one embodiment, the p-connection regions and the n-connection regions are arranged in a checkerboard pattern when viewed from a top view. This may mean that the n-connection regions and the p-connection regions alternate in lateral directions. So, there is a p-connection element arranged between every two n-connection elements, and vice versa. In this manner, the current impression may be designed flexibly.

According to at least one embodiment, the at least one p-connection region and the at least one n-connection region are formed as concentric rings when viewed from a top view. If the laser comprises a plurality of n-connection regions and a plurality of p-connection elements, the connection regions forming rings may be arranged alternately. In this case, for example, a first n-connection region may form the innermost ring or circle, when viewed from a top view, and may be surrounded by a first p-connection region in the shape of a ring. A second n-connection region may surround the first p-connection region in a ring shape, and a second p-connection region may surround the second n-connection region in a ring shape, and so on. The rings therefore have varying diameters. Alternatively, an innermost ring may be formed by a p-connection region. In this manner, the current impression may be designed flexibly in order to excite certain optical modes.

According to at least one embodiment, the laser comprises at least one first electrical contact element. A respective first electrical contact element is arranged on each p-connection region and assigned thereto. According to at least one embodiment, the laser comprises at least one second electrical contact element. A respective second electrical contact element is arranged on each n-connection region and assigned thereto. The first and second contact elements may comprise a highly doped semiconductor material and/or a metal. The first and second electrical contact elements preferably comprise or consist of a metal, such as Ag, Pt, Au, Pd, Ti. Alternatively or additionally, the first and second electrical contact elements may also comprise or consist of a transparent conductive oxide, TCO for short, such as indium tin oxide, ITO for short, or zinc oxide. In addition, the first and second electrical contact elements may simultaneously form the reflective layer, as discussed above, especially if they comprise a metal. In particular, the first and second electrical contact elements are spaced apart and separated from each other. Since a contact element may be associated with each connection region, the laser may comprise a plurality of electrical contact elements, in particular as many electrical contact elements as there are connection regions. For example, the laser comprises at least four or at least ten or at least 100 first electrical contact elements and/or at least four or at least ten or at least 100 second electrical contact elements. The first and second electrical contact elements connect the connection regions (p- or n-connection regions) to a source of charge carriers. In this manner, electrons may be guided to the active layer via the second electrical contact elements and the n-connection regions, while holes may be guided to the active layer via the first electrical contact elements and the p-connection regions.

According to at least one embodiment, an optoelectronic system is disclosed. The optoelectronic system comprises a surface-emitting photonic-crystal laser according to the embodiments disclosed above. This means that all of the features disclosed for the PCSEL are also disclosed for the optoelectronic system and vice versa. The PCSEL may be integrated into the optoelectronic system. For example, the optoelectronic system is a LIDAR system. However, the optoelectronic system may also comprise other systems, in particular systems involving pulse applications (short pulses with high powers), for which high output power, monomodality and/or a narrow beam profile of the laser beam are desirable. For example, a power of the laser may be between 10 W and 1000 W. For example, the laser may be electrically supplied with currents between 10 A and 1000 A. The high powers and currents, as well as the narrow beam profile, may be achieved in particular by using surfaces of any size (in the top view). The surface emission also allows for the PCSEL to be integrated into the optoelectronic system more efficiently in comparison to edge-emitting lasers.

According to at least one embodiment, a method of manufacturing a surface-emitting photonic-crystal laser is disclosed. All features disclosed for the laser are also disclosed for manufacturing methods and vice versa.

The method comprises forming a second waveguide layer. For example, the second waveguide layer is formed by epitaxial growth on a semiconductor substrate. The semiconductor substrate may comprise one of the above-mentioned material systems. Alternatively, the second waveguide layer may be formed by epitaxial growth on a second cladding layer, the second cladding layer having been grown on the semiconductor substrate in a step preceding this step.

According to at least one embodiment, the method further comprises applying an active layer to the second waveguide layer, the active layer being configured to generate electromagnetic radiation by charge carrier recombination. The active layer may comprise a plurality of semiconductor layers, in particular a layer stack of materials of different band gaps to form at least one quantum well. The active layer may be formed by epitaxial growth on the second waveguide layer.

According to at least one embodiment, the method further comprises applying a first waveguide layer to the active layer. The first waveguide layer may be formed by epitaxial growth on the active layer. The first waveguide layer and the second waveguide layer together form a waveguide for guiding optical modes.

According to at least one embodiment, the method further comprises applying a first cladding layer to the first waveguide layer. The first cladding layer may be formed by epitaxial growth on the first waveguide layer. The first cladding layer and the second cladding layer (if present) have a lower refractive index than the waveguide layers. A laterally traveling optical wave is thus kept in the waveguide by reflection at the interface.

According to at least one embodiment, the method further comprises applying a contact layer by epitaxial growth on the first cladding layer. The contact layer may be part of a subsequent electrical contact element. The contact layer may comprise a highly doped semiconductor material. For example, the contact layer is n-doped. According to at least one embodiment, the contact layer is patterned in a further process step. This may mean that at least parts of the contact layer are removed in order to expose the underlying first cladding layer. The contact layer may prevent pn transitions in the cladding layer and thus losses.

According to at least one embodiment, the method further comprises forming at least one p-connection region of the first cladding layer for injecting electrically positive charge carriers into the active layer. For example, the at least one p-connection region is formed by ion implantation into the exposed regions of the first cladding layer, wherein a lithographic step may be used.

According to at least one embodiment, the method further comprises forming at least one n-connection region of the first cladding layer for injecting electrically negative charge carriers into the active layer. The at least one n-connection region may possibly be formed by the region covered by the contact layer. The n-connection region may be undoped. This may mean that the first cladding layer was undoped at the time it was deposited, with the p-type connection region having been made p-type conductive by the above-mentioned ion implantation, and the n-type connection region remained undoped. The n-connection region may be or become defined by the region of the first cladding layer that is not formed as a p-connection region, i.e. that was doped by means of ion implantation in the previous step, for example. Alternatively, the at least one n-connection region is likewise formed by means of ion implantation, wherein a lithography step may be used. In this case, the n-connection region may be doped, in particular using an n-type dopant, in order to obtain increased n-type conductivity. Charge carriers may diffuse from only one side to the active layer through the p- and n-terminal regions. Shadowing effects and/or absorption effects may thus be avoided.

According to at least one embodiment, the method further comprises forming regions and further regions of the second waveguide layer which are periodically arranged with respect to one another, wherein a refractive index of the regions differs from a refractive index of the further regions, and wherein the regions and the further regions form a photonic crystal. A standing optical wave may be formed by the photonic crystal and radiation may be outcoupled perpendicular to the main extension plane of the active layer. Angles other than 90° are also conceivable.

According to at least one embodiment, forming regions and further regions of the second waveguide layer which are periodically arranged with respect to one another comprises forming trenches or holes in the second waveguide layer. The trenches/holes extend from a surface of the second waveguide layer facing away from the active layer into the second waveguide layer. Alternatively, if a second cladding layer is present, the trenches/holes may extend from a surface of the second cladding layer facing away from the active layer into the second waveguide layer. The regions of the second waveguide layer are defined by a material of the second waveguide layer, in particular by the semiconductor material used. The further regions are defined by recesses formed by the trenches or holes. This means that the further regions are formed by air or a gas. According to at least one embodiment, the recesses may be filled with a further material, e.g. by means of atomic layer deposition. In this case, the further regions are formed by the further material, e.g. an oxide. The trenches or holes may be formed using electron beam lithography, nano-embossing lithography, UV/DUV/EUV lithography and/or etching. A diameter of the trenches/holes may therefore be between 5 nm and 100 nm, or between 10 nm and 50 nm. By introducing trenches, the photonic crystal may be formed efficiently. Furthermore, regrowth of the photonic crystal structure is not necessary.

In an alternative embodiment, the regions or the further regions of the first waveguide layer may be formed by patterning during growth and subsequent regrowth. For example, the second waveguide layer is patterned by electron beam lithography and inductively coupled plasma and then epitaxially regrown to embed a plurality of voids in the layer. The further regions of the second waveguide layer may, for example, be defined by the cavities, while the regions may be defined by the semiconductor material of the second waveguide layer, or vice versa. In this embodiment, the further regions may accordingly be embedded in the second waveguide layer, i.e. completely surrounded by it. In particular, the further regions do not extend to the surface of the second waveguide layer. Also, the cavities may be filled with another material. By using the manufacturing process described, a defect-free or at least low-defect waveguide layer may be formed.

According to at least one embodiment, the method further comprises applying a first electrical contact element to each of the p-connection regions and/or applying a second electrical contact element to each of the n-connection regions. The first and second electrical contact elements may preferably comprise or consist of a metal. The first and second electrical contact elements may be applied, for example, by means of a sputtering process or another deposition process. It is also possible for the above patterned contact layer to be part of the first or second electrical contact elements. The electrical contact elements connect the connection regions of the cladding layer to a source of electrical charge carriers. In addition, the electrical contact elements may be configured as a reflective layer in order to reflect electromagnetic radiation scattered by the photonic crystal.

Further embodiments of the manufacturing process will become apparent to the skilled reader from the above embodiments for the PCSEL. In both the preceding and the following parts, the specification equally relates to the laser, the optoelectronic system, and the manufacture of the laser.

### BRIEF DESCRIPTION OF THE DRAWINGS

Further advantages, advantageous embodiments and further developments become apparent from the exemplary embodiments described below in conjunction with the figures.

In the exemplary embodiments and the figures, identical, similar or similarly effective elements may each be designated by the same reference numerals. The elements shown and their relative sizes are not to be regarded as true to scale; rather, individual elements, such as layers, components, structural elements, and regions, may be shown in exaggerated size for better illustration and/or understanding.

FIGS. 1 to 4 show a cross-section of a surface-emitting photonic-crystal laser according to embodiments.

FIGS. 5 to 7 show a top view of a surface-emitting photonic-crystal laser according to embodiments.

FIG. 8 shows a schematic representation of an optoelectronic system according to an exemplary embodiment.

FIGS. 9 to 13 show intermediates in the manufacture of a PCSEL according to an exemplary embodiment.

FIG. 14 shows an end product in the manufacture of a PCSEL according to an exemplary embodiment.

### DETAILED DESCRIPTION

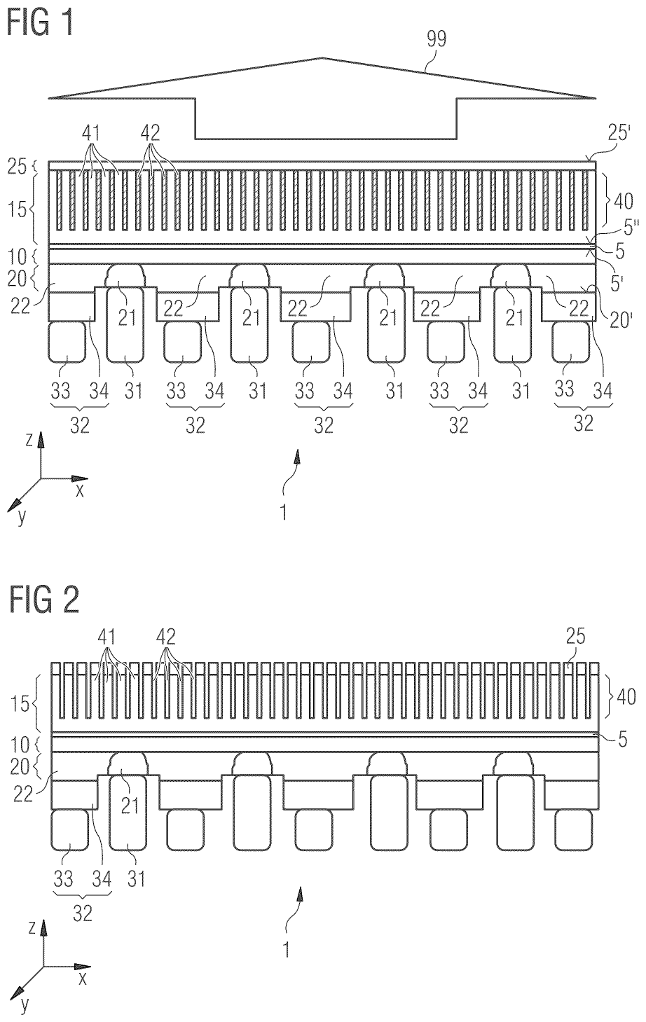

Referring to FIG. 1, a surface-emitting photonic-crystal laser 1, PCSEL, is shown. The PCSEL 1 comprises an active layer 5 which is configured to generate electromagnetic radiation 99 (illustrated by an arrow, following interaction with a photonic crystal) by charge carrier recombination. The active layer may comprise a semiconductor material. The active layer 5 comprises a first main surface 5′ and a second main surface 5″ opposite the first main surface 5′. The active layer comprises a main extension plane extending in lateral directions x, y. In a transversal direction z, which is perpendicular to the main extension plane, the active layer has a thickness. The first main surface 5′ and second main surface 5″ are parallel to the lateral directions x, y. The active layer 5 may be formed by a plurality of layers (not shown). In particular, the active layer 5 may form at least one quantum well, which is intended and configured to emit electromagnetic radiation 99 of a predetermined wavelength when a driving current is applied. For example, the at least one quantum well is a 2D quantum well formed by a thin intermediate layer of a first material surrounded by barrier layers of a second material. The barrier layers have a larger band gap than the intermediate layer.

The PCSEL 1 further comprises a first waveguide layer 10 arranged on the first main surface 5′ and a second waveguide layer 15 arranged on the second main surface 5″. In other words, the active layer 5 is arranged between the first waveguide layer 10 and the second waveguide layer 15 and forms a respective interface therewith. The waveguide layers 10, 15 may comprise a semiconductor material. In the exemplary embodiment of FIG. 1, a thickness of the first waveguide layer 10 is less than a thickness of the second waveguide layer 15. Herein, the thicknesses of the waveguide layers 10, 15 refer to an expansion of the waveguide layers 10, 15 in the transversal direction z. The first waveguide layer 10 together with the second waveguide layer 15 forms a waveguide into which the active layer 5 is embedded. In the exemplary embodiment shown the different thicknesses of the waveguide layers 10, 15 result in an asymmetrical waveguide profile. The first waveguide layer 10 and the second waveguide layer 15 may be doped, undoped or intrinsically doped. However, the second waveguide layer 15 is preferably undoped or intrinsically doped.

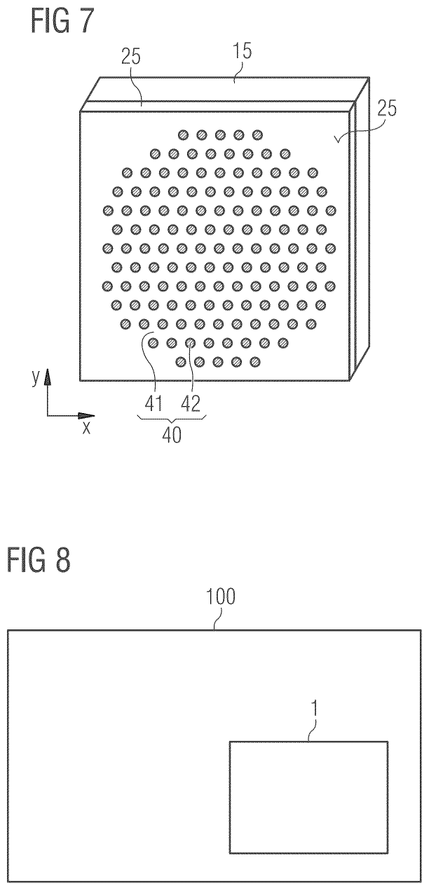

The second waveguide layer 15 comprises regions 41 and further regions 42 arranged periodically with respect to one another. A refractive index of the regions 41 differs from a refractive index of the further regions 42. In this manner, the regions 41 and the further regions 42 form a photonic crystal 40. The electromagnetic radiation 99 is emitted in the transversal direction z due to interaction with the photonic crystal 40. The regions 41 and the further regions 42 may comprise different materials. For example, the regions 41 comprise a semiconductor material, while the further regions comprise another semiconductor material, air, gas, or an oxide. A difference of refractive indices between the regions 41 and the further regions 42 may be large. The further regions 42 may have been subsequently introduced into the waveguide layer 15. This may mean that the waveguide layer 15 is initially formed as a continuous layer comprising the material of the regions 41. The further regions 42 may be formed by changing the material, removing material or replacing material. The further regions 42 may be arranged in a matrix or may be located on intersections of a lattice, when viewed from a top view (see FIG. 7). The lattice may consist of a base comprising several elements. A lattice period may be chosen such that it substantially coincides with a wavelength of the radiation 99 generated by the active layer 5, or represents an integer or non-integer multiple thereof. In the exemplary embodiment shown in FIG. 1, the further regions 42 extend from a surface of the second waveguide layer 15 facing away from the active layer 5 into the second waveguide layer 15. In the transversal direction z, the further regions 42 are spaced apart from the active layer 5. It is also possible (but not shown) for the further regions 42 to be embedded in the second waveguide layer 15, i.e. to not extend to the surface of the second waveguide layer 15. Such an arrangement may, for example, be produced using a regrowth process. In this case, the further regions 42 may, for example, be formed by cavities or self-contained zones in the second waveguide layer 15.

The PCSEL 1 further comprises a first cladding layer 20 arranged on the first waveguide layer 10. The first cladding layer 20 forms an interface with the first waveguide layer 10, i.e. the first waveguide layer 10 is arranged between the first cladding layer 20 and the active layer 5. The first cladding layer 20 comprises a semiconductor material, for example. The first cladding layer is preferably doped at least in certain regions. The first cladding layer 20 comprises at least one p-connection region 21 for injecting electrically positive charge carriers into the active layer 5. The p-connection region may be formed, for example, by doping a region of the first cladding layer 20 with a p-type dopant. The first cladding layer 20 also comprises at least one n-connection region 22 for injecting electrically negative charge carriers into the active layer 5. The n-connection region may be formed, for example, by doping a further region of the first cladding layer 20 with an n-type dopant. The example shown shows a plurality of p-type and n-type connection regions, which may be electrically controlled independently and individually via contact elements 31, 32. The first cladding layer 20 forms a surface 20′. The surface 20′ is opposite the first waveguide layer 10, i.e. faces away from it. The surface 20′ may also be referred to as the connection side 20′.

The PCSEL 1 of FIG. 1 further comprises a second cladding layer 25, which is arranged on the second waveguide layer 15. The second cladding layer 25 forms an interface with the second waveguide layer 15. In other words, the second waveguide layer 15 is arranged between the second cladding layer 25 and the active layer 5. The second cladding layer 25 is optional. The second cladding layer 25 may comprise a semiconductor material. The second cladding layer 25 may preferably be undoped. The second cladding layer 25 may be thinner in the transversal direction z than the first cladding layer 20. The second cladding layer 25 forms a surface 25′. The surface 25′ is opposite the second waveguide layer 15, i.e. faces away from it. The surface 25′ may also be referred to as the emission side 25′. This may mean that the electromagnetic radiation 99 generated by the active layer 5 is emitted from the PCSEL 1 via the emission side 25′ following manipulation by the photonic crystal 40.

The PCSEL 1 according to FIG. 1 further comprises a contact layer 34. The contact layer 34 is arranged on the first cladding layer 20, i.e. on the contact side 20′, at least in certain regions. The contact layer 34 may be a highly doped semiconductor layer. The contact layer 34 may be part of a first or a second contact element 31, 32, by means of which the at least one n- or p-connection region 21, 22 is electrically contacted. In the example shown, the contact layer 34 is part of the second contact element 32, by means of which the n-connection region 22 is electrically contacted. The contact layer 34 is patterned such that only n-connection regions 22 of the first cladding layer 20 are covered by it and the other regions of the first cladding layer 20, which correspond to the p-connection regions 22, are exposed.

The PCSEL 1 according to FIG. 1 further comprises a further contact layer 33 which is arranged on the contact layer 34. The further contact layer 33 may comprise a metal, for example. The further contact layer 33 is patterned and covers regions of the contact layer 34. The contact layer 34 and the further contact layer 33 together form the second contact element 32. The PCSEL 1 comprises a plurality of second contact elements 32, corresponding to the number of n connection regions 22. The PCSEL 1 further comprises a first contact element 31 which is arranged on the p-connection region. The first contact element 31 may comprise a metal, for example. The first contact element 31 is patterned and covers the p-connection regions 21. The PCSEL 1 comprises a plurality of first contact elements 31, corresponding to the number of p-connection regions 21.

Referring to FIG. 2, a further exemplary embodiment of the PCSEL 1 is shown. The exemplary embodiment of FIG. 2 differs from the exemplary embodiment of FIG. 1 in that the further regions 42 of the second waveguide layer 15 are formed by recesses in the second waveguide layer 15. Here, the recesses of the second waveguide layer 15 are formed by trenches or holes extending from the surface 25′ of the second cladding layer 25 into the second waveguide layer 15. The second cladding layer 25 is again optional. A diameter of the trenches may be in the nanometer range. The shape of the trenches may be cylindrical, i.e. when viewed from a top view, the trenches may have a circular or elliptical profile (see FIG. 7). However, it is also possible for the trenches to have a different profile, e.g. polygonal, in particular triangular or quadrangular. In the transversal direction z, the trenches may reach close to the active layer 5. However, a trench foot of the trenches remains at a distance from the active layer 5.

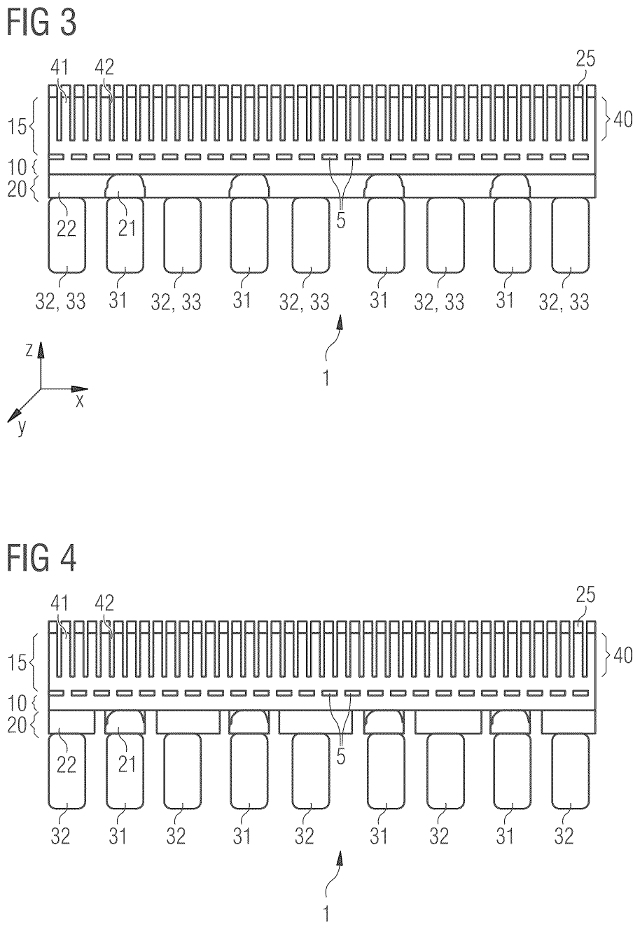

Referring to FIG. 3, a further exemplary embodiment of the PCSEL 1 is shown. The exemplary embodiment of FIG. 3 differs from the exemplary embodiment of FIG. 2 in that the active layer 5 uses a plurality of 0-dimensional quantum dots (structures limited in all three spatial directions) or 1-dimensional quantum wires (in this case, the structures only extend in the lateral y-direction, out of the image plane). The density of the quantum dots or quantum wires may vary along lateral directions x, y, for example. More radiation is then generated in regions of higher density than in regions of lower density. In this manner, the position of the radiation-emitting regions of the active layer 5 may be further adjusted. Furthermore, the PCSEL 1 of FIG. 3 does not comprise a contact layer 34. The first contact elements 31 are in direct contact with the p-connection regions 21. The second contact elements 32, consisting of the further contact layer 33, are in direct contact with the n-connection regions 22. The first cladding layer 20 is formed by a continuous layer in which the p-connection regions 21 and the n-connection regions 22 alternate laterally.

Referring to FIG. 4, a further exemplary embodiment of the PCSEL 1 is shown. The exemplary embodiment of FIG. 4 differs from the exemplary embodiment of FIG. 3 in that the p-connection regions 21 and the n-connection regions 22 are no longer part of a simply contiguous first cladding layer 20. Instead, the p-connection regions 21 and the n-connection regions 22 are separate and spaced-apart elements. For example, the first cladding layer 20 shown in the previous figures was patterned for this purpose. By configuring the connection regions 21, 22 as spaced-apart and separate elements, recombination of charge carriers outside the active layer 5 may be suppressed and pn junctions in the first cladding layer 20 may be avoided.

Referring to FIG. 5, a further exemplary embodiment of the PCSEL 1 is shown in a top view. The top view here refers to a view of the connection side 20′ of the first cladding layer 20. As may be seen in FIG. 5, the first contact elements 31 and the second contact elements 32 are arranged in a checkerboard pattern. This means that a second contact element 32 is arranged between every two first contact elements 31 in lateral directions x, y, and vice versa. In this example, the PCSEL 1 comprises 8 first and 8 second contact elements 31, 32 which are arranged in a 4×4 array. These numbers are to be understood as arbitrary examples, and the PCSEL 1 may be expanded or reduced to larger or smaller areas comprising more or less than a total of 16 contact elements 31, 32. In addition, the lateral diameters of the contact elements 31, 32 may be adjusted as desired with respect to the area of the connection side 20′. The number of first contact elements 31 (and thus the number of p-connection regions 21) may differ from the number of second contact elements 32 (and thus the number of n-connection regions 22).

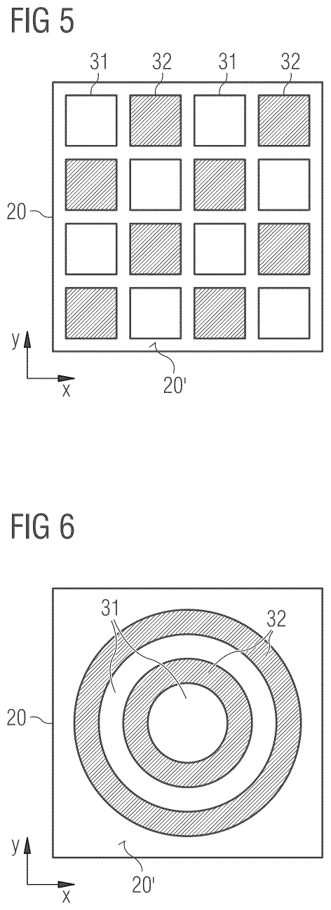

Referring to FIG. 6, an alternative exemplary embodiment of a PCSEL 1 is shown in a top view of the connection side 20′.

In this case, the first and second contact elements 31, 32 are formed as concentric rings or circles of different diameters. A second ring-shaped electrical contact element 32 surrounds a first innermost first contact element 31 in lateral directions x, y. A further ring-shaped first contact element 31 surrounds the second electrical contact element 32, and a further ring-shaped second contact element 32 surrounds the further first contact element 31. This scheme may be extended as desired and/or may start with a second contact element 32 as the innermost contact element.

Referring to FIG. 7, an exemplary embodiment of the PCSEL 1 is shown in a top view of the emission side 25′. Only the second cladding layer 25 and the underlying second waveguide layer 15 are shown, further layers are not shown for reasons of clarity. As may be seen, the further regions 42 are formed as trenches that extend from the emission side 25′ into the second waveguide layer 15. The areas of the second waveguide layer 15 located between the trenches form the regions 41 of the second waveguide layer 15. By way of example, the trenches are arranged in a hexagonal grid. The regions 41 and the further regions 42 form the photonic crystal 40.

As indicated in FIG. 8, the PCSEL 1 may be integrated into an optoelectronic system 100. For example, the optoelectronic system 100 is a LIDAR system. The optoelectronic system 100 may also include other systems in which VCSELs (vertical cavity surface-emitting lasers) or EELs (edge-emitting lasers) are commonly used. The electrical contact elements 31, 32 of the PCSEL 1 may be connected to a printed circuit board or PCB or to another semiconductor device (e.g. a driver IC) of the optoelectronic system 100 by means of wire bonds or flip-chip mounting. The optoelectronic system 100 may include further optical and/or electronic components, such as optical filters, lenses, photodetectors and/or integrated circuits.

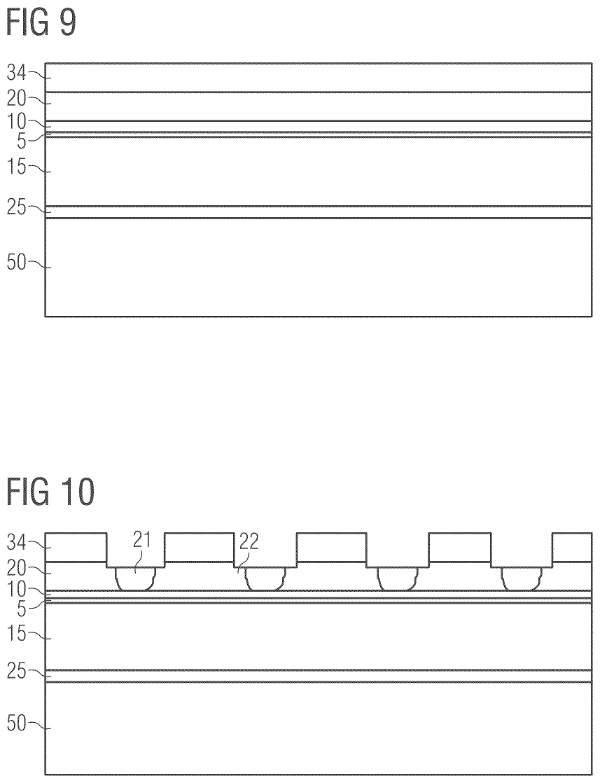

FIGS. 9-14 show a possible manufacturing process for a PCSEL 1. FIG. 9 shows a layer stack that may be formed by epitaxial growth. The layer stack comprises a substrate 50, which may be a semiconductor substrate. The second cladding layer 25 is formed on the substrate 50. However, the second cladding layer 25 is optional, as explained above. As first layers on the substrate 50, for example, a buffer layer for improving growth and/or a release layer, which facilitates subsequent detachment of the substrate 50 or the buffer layer, may be deposited.

The second waveguide layer 15 is formed on the second cladding layer 25. The second waveguide layer 15 may also be formed directly on the substrate 50 (or the buffer layer or the release layer). The active layer 5, which is configured to generate electromagnetic radiation 99 by charge carrier recombination, is applied to the second waveguide layer 15. The first waveguide layer 10 is applied to the active layer 5. The first cladding layer 20 is applied to the first waveguide layer 10. In the example shown, the contact layer 34, which may in particular be a highly doped n-type semiconductor layer, is applied to the first cladding layer 20. The contact layer 34 is optional.

FIG. 10 shows the intermediate product of FIG. 9 after further process steps. According to FIG. 10, the contact layer 34 is patterned such that regions of the underlying first cladding layer 20 are exposed. Furthermore, p-connection regions 21 of the first cladding layer 20 are formed for injecting electrically positive charge carriers into the active layer. The p-connection regions 21 may be formed using ion implantation, for example. Alternatively, connection regions for different charge carriers may also be created by multiple growth processes. The details of such a process sequence may be deduced by a person skilled in the art. Furthermore, n-connection regions 22 of the first cladding layer 20 are formed for injecting electrically negative charge carriers into the active layer 5. The n-connection regions 22 may be defined, for example, by the regions of the first cladding layer 20 that are not formed as p-connection regions 21. In the example shown, the n-connection regions 22 are covered by the contact layer 34.

FIG. 11 shows the intermediate product of FIG. 10 after further process steps. According to FIG. 11, the further contact layer 33 is applied to the contact layer 34 or to its regions. The further contact layer 33 may comprise a metal and may be formed by means of a sputtering process. The contact layer 34 and the further contact layer 33 form the second electrical contact elements 32, which are consequently arranged on each of the n-connection regions 22. Furthermore, first contact elements 31 are applied to each of the p-connection regions. The first contact elements 31 may also preferably comprise a metal and be formed by means of a sputtering process.

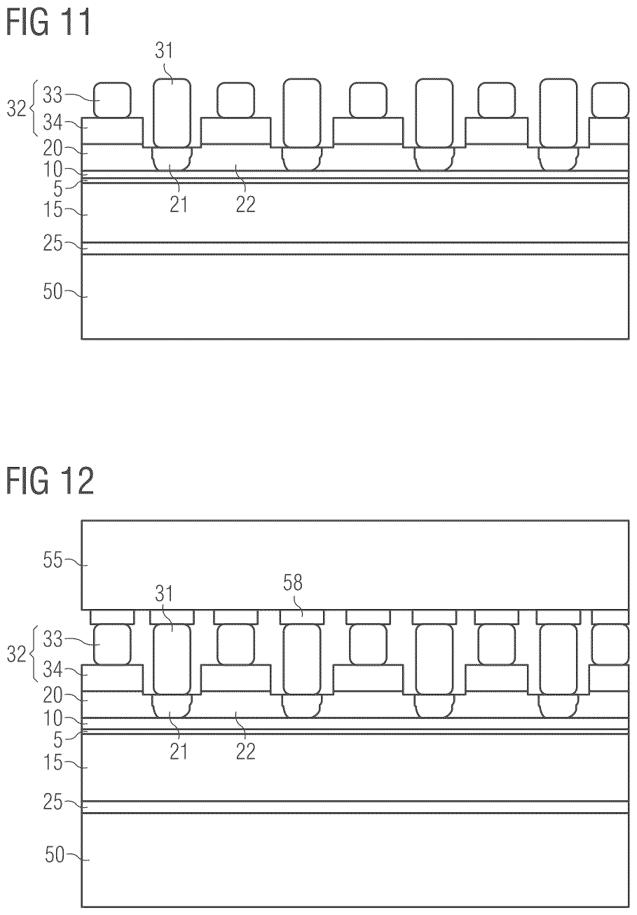

FIG. 12 shows the intermediate product of FIG. 11 after further process steps. According to FIG. 12, the first and second contact elements 31, 32 are bonded to a further substrate 55. A bonding process may be used for this purpose. The further substrate 55 may have bonding pads 58 by means of which the respective contact elements 31, 32 are bonded to the further substrate 55. The further substrate 55 may be a carrier substrate which is removed again after the manufacturing process. Preferably, however, the further substrate 55 may comprise an application-specific integrated circuit, or ASIC for short. The circuit may comprise a plurality of switches, which may be transistors, in particular thin film transistors. Each switch may be electrically connected to at least one of the contact elements 31, 32. In this manner, the contact elements 31, 32, and therefore the connection regions 21, 22, may be controlled separately.

FIG. 13 shows the intermediate product of FIG. 12 after further process steps. According to FIG. 13, the intermediate product is rotated by 180° such that the additional substrate 55 acts as a carrier. Furthermore, the substrate 50 is removed, for example by grinding and/or etching. This exposes the second cladding layer 25. Alternatively, if no second cladding layer 25 is present, the second waveguide layer 15 is exposed. In this case, in an optional step, the second cladding layer 25 might now be formed by a deposition process. Alternatively, the second waveguide layer 15 may also be formed by a deposition process.

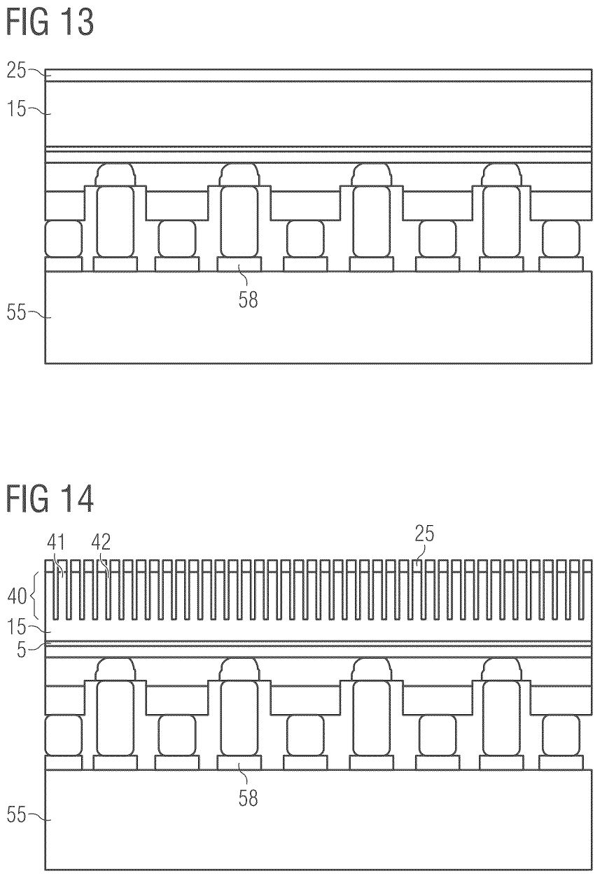

FIG. 14 shows the end product of the manufacturing process of FIGS. 9 to 13 after further process steps. By means of a patterning process (e.g. electron beam lithography and etching etc.), trenches are introduced into the optional second cladding layer 25 and the underlying second waveguide layer 15. As a result, regions 41 and further regions 42 of the second waveguide layer 15 are formed which are periodically arranged with respect to one another. The trenches form recesses in the second waveguide layer 15, which may be filled with air or gas. As a result, a refractive index of the regions 41 differs from a refractive index of the further regions 42, thereby forming a photonic crystal 40.

The features and embodiments described in conjunction with the figures may be combined with one another according to further embodiments, even if not all combinations have been explicitly described. Furthermore, the embodiments described in conjunction with the figures may alternatively or additionally comprise further features as described in the general part of the specification.

The invention is not limited by the description to the exemplary embodiments described. Rather, the invention includes any new feature as well as any combination of features, which includes in particular any combination of features in the patent claims, even if this feature or combination itself is not explicitly stated in the patent claims or embodiments.

1. A surface-emitting photonic-crystal laser (1), comprising:
an active layer for generating electromagnetic radiation by charge carrier recombination, the active layer comprising a first main surface and a second main surface opposite the first main surface,
a first waveguide layer arranged on the first main surface,
a second waveguide layer arranged on the second main surface and comprising regions and further regions arranged periodically with respect to one another, wherein a refractive index of the regions differs from a refractive index of the further regions, and wherein the regions and the further regions form a photonic crystal, and
a first cladding layer arranged on the first waveguide layer, the first cladding layer comprising at least one p-connection region for injecting electrically positive charge carriers into the active layer and at least one n-connection region for injecting electrically negative charge carriers into the active layer.

2. The surface-emitting photonic-crystal laser according to claim 1, wherein the second waveguide layer comprises a material which defines the regions of the second waveguide layer, and wherein the further regions of the second waveguide layer are defined by recesses of the second waveguide layer.

3. The surface-emitting photonic-crystal laser according to claim 2, wherein the recesses of the second waveguide layer are formed by trenches or holes in the second waveguide layer, the trenches or holes extending from a surface of the second waveguide layer facing away from the active layer into the second waveguide layer.

4. The surface-emitting photonic-crystal laser according to claim 1, wherein the first waveguide layer is undoped or intrinsically doped.

5. The surface-emitting photonic-crystal laser according to claim 1, wherein the second waveguide layer is undoped or intrinsically doped.

6. The surface-emitting photonic-crystal laser according to claim 1, wherein a thickness of the first waveguide layer is less than a thickness of the second waveguide layer.

7. The surface-emitting photonic-crystal laser according to claim 1, further comprising a second cladding layer arranged on the second waveguide layer.

8. The surface-emitting photonic-crystal laser according to claim 2, wherein the recesses of the second waveguide layer are formed by trenches in the second waveguide layer which extend from a surface of the second cladding layer facing away from the second waveguide layer into the second waveguide layer.

9. The surface-emitting photonic-crystal laser according to claim 7, wherein the second cladding layer is undoped or intrinsically doped.

10. The surface-emitting photonic-crystal laser according to claim 1, wherein the active layer forms at least one quantum well which is configured and formed to emit electromagnetic radiation of a predetermined wavelength when a driving current is applied.

11. The surface-emitting photonic-crystal laser according to claim 1, wherein a radiation direction of the laser is perpendicular to a main extension plane of the second waveguide layer and electromagnetic radiation is outcoupled via a surface of the second waveguide layer facing away from the active layer.

12. The surface-emitting photonic-crystal laser according to claim 1, further comprising a reflective layer arranged on or above the first cladding layer.

13. The surface-emitting photonic-crystal laser according to claim 1, wherein the first cladding layer comprises a plurality of individually and independently controllable p-connection regions and/or a plurality of individually and independently controllable n-connection regions.

14. The surface-emitting photonic-crystal laser according to claim 13, wherein the p-connection regions and the n-connection regions are arranged in a checkerboard pattern when viewed from a top view.

15. The surface-emitting photonic-crystal laser according to claim 1, wherein the at least one p-connection region and the at least one n-connection region are formed as concentric rings when viewed from a top view.

16. The surface-emitting photonic-crystal laser according to claim 1, further comprising at least one first electrical contact element and at least one second electrical contact element, wherein a respective first electrical contact element is arranged on and associated with each p-connection region, and wherein a respective second electrical contact element is arranged on and associated with each n-connection region.

17. An optoelectronic system comprising a surface-emitting photonic-crystal laser according to claim 1.

18. A method of manufacturing a surface-emitting photonic-crystal laser, comprising:
forming a second waveguide layer,
applying an active layer to the second waveguide layer, the active layer being formed to generate electromagnetic radiation by charge carrier recombination,
applying a first waveguide layer to the active layer,
applying a first cladding layer to the first waveguide layer,
forming at least one p-connection region of the first cladding layer for injecting electrically positive charge carriers into the active layer and at least one n-connection region of the first cladding layer for injecting electrically negative charge carriers into the active layer, and
forming regions and further regions of the second waveguide layer arranged periodically with respect to one another, wherein a refractive index of the regions differs from a refractive index of the further regions, and wherein the regions and the further regions form a photonic crystal.

19. The method according to claim 18, further comprising applying a first electrical contact element to each of the p-connection regions, and applying a second electrical contact element to each of the n-connection regions.

20. The method according to claim 18, wherein forming regions and further regions of the second waveguide layer arranged periodically with respect to one another comprises:
forming trenches or holes in the second waveguide layer, which extend from a surface of the second waveguide layer facing away from the active layer into the second waveguide layer,
wherein the regions are defined by the waveguide material, and the further regions are defined by recesses formed by the trenches or holes.
